(19) United States
(12) Patent Application Publication
(10) Pub. No.: US 2025/0133732 A1
(43) Pub. Date: Apr. 24, 2025

(54) SEMICONDUCTOR MEMORY DEVICE

(71) Applicant: Samsung Electronics Co., Ltd., Suwon-si (KR)

(72) Inventor: Hyeon Song CHA, Suwon-si (KR)

(21) Appl. No.: 18/814,041

(22) Filed: Aug. 23, 2024

(30) Foreign Application Priority Data
Oct. 23, 2023 (KR) 10-2023-0141818

(51) Int. Cl. H10B 12/00

(52) U.S. Cl. CPC H10B 12/50; H10B 12/315

(57) ABSTRACT

A semiconductor memory device comprising a substrate including a cell area and a peripheral area; a peripheral gate structure disposed on the substrate and in the peripheral area thereof; a peripheral wiring line connected to the substrate disposed on the peripheral gate structure and connected to the substrate; a peripheral etch stop film disposed on the peripheral wiring line; an element isolation film defining an active area in the cell area disposed in the substrate and in the cell area thereof to define an active area in the cell area; a storage pad connected to the active area defined in the cell area; a cell etch stop film disposed on the storage pad; and a capacitor structure extending through the cell etch stop film to contact the storage pad, wherein the peripheral etch stop film and the cell etch stop film respectively include materials different from each other.

### CROSS-REFERENCE TO RELATED APPLICATION

This application claims priority under 35 U.S.C. § 119 from Korean Patent Application No. 10-2023-0141818, filed on Oct. 23, 2023, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor memory device.

### Description of Related Art

A semiconductor memory device has an increasingly higher integration level. Thus, in order to implement more semiconductor elements in the same area, individual circuit patterns are increasingly smaller. In other words, as the integration level of the semiconductor memory device increases, a design rule for components of the semiconductor memory device is decreasing.

In a highly-scaled semiconductor memory device, a process of forming a plurality of wire lines and a plurality of buried contacts (BC) interposed between the lines is becoming increasingly complex and difficult.

### SUMMARY

A technical purpose of the present disclosure is to provide a semiconductor memory device that has improved reliability and performance.

Purposes in accordance with the present disclosure are not limited to the above-mentioned purpose. Other purposes and advantages in accordance with the present disclosure in addition to those mentioned above may be understood from following descriptions and more clearly understood from embodiments in accordance with the present disclosure. Further, it will be readily appreciated that the purposes and advantages in accordance with the present disclosure may be realized by features and combinations thereof as disclosed in the claims.

According to some example embodiments of the present inventive concepts, a semiconductor memory device including a substrate including a cell area and a peripheral area; a peripheral gate structure on the substrate and in the peripheral area; a peripheral wiring line on the peripheral gate structure and connected to the substrate; a peripheral etch stop film disposed on the peripheral wiring line; an element isolation film defining an active area in the cell area; a storage pad connected to the active area defined in the cell area; a cell etch stop film disposed on the storage pad; and a capacitor structure extending through the cell etch stop film so as to contact the storage pad, wherein the peripheral etch stop film and the cell etch stop film include materials different from each other.

According to some example embodiments of the present inventive concepts, a semiconductor memory device including a substrate including a cell area, a peripheral area, and an interface area between the cell area and the peripheral area; a peripheral gate structure disposed on the substrate and in the peripheral area; a peripheral wiring line disposed on the peripheral gate structure; an element isolation film defining an active area in the cell area in the substrate; a storage pad disposed on the active area defined in the cell area; a peripheral etch stop film that is disposed on the peripheral wiring line and is not disposed on the storage pad; a cell etch stop film that is disposed on the storage pad and is not disposed on the peripheral gate structure; and a capacitor structure extending through the cell etch stop film so as to contact the storage pad.

According to some example embodiments of the present inventive concepts, a semiconductor memory device including a substrate including a cell area, a peripheral area, and an interface area between the cell area and the peripheral area; a cell area isolation film defining the cell area disposed in the substrate and in the interface area; a bit-line structure disposed on the substrate and in the cell area, wherein the bit-line structure includes a cell conductive line and a cell line capping film disposed on the cell conductive line; a cell gate electrode disposed in the substrate and in the cell area and intersecting the cell conductive line; an element isolation film defining an active area in the substrate and in the cell area; a storage pad disposed on a side surface of the bit-line structure and connected to the active area; a cell etch stop film disposed on the storage pad; a capacitor structure including: a lower electrode extending through the cell etch stop film so as to contact the storage pad; a capacitor dielectric film disposed on the lower electrode; and an upper electrode disposed on the capacitor dielectric film; a peripheral gate structure disposed on the substrate and in the peripheral area; a peripheral wiring line disposed on the peripheral gate structure and connected to the substrate; and a peripheral etch stop film disposed on the peripheral wiring line, wherein a side end of the cell etch stop film is disposed on the cell area isolation film disposed in the interface area.

### BRIEF DESCRIPTION OF DRAWINGS

The above and other aspects and features of the present disclosure will become more apparent by describing in detail illustrative embodiments thereof with reference to the attached drawings, in which:

FIG. 1 is a schematic layout diagram of a semiconductor memory device according to example embodiments;

FIG. 2 is a schematic layout of area R1 in FIG. 1;

FIG. 3 is a schematic layout diagram of area R2 in FIG. 1;

FIG. 4 is an illustrative cross-sectional view taken along a line A-A in FIG. 1;

FIG. 5 is a cross-sectional view cut along a line B-B in FIG. 3;

FIG. 6 is a cross-sectional view cut along a line C-C in FIG. 3;

FIG. 7 to FIG. 10 are diagrams for illustrating a semiconductor memory device according to example embodiments;

FIG. 11 is a layout diagram for illustrating a semiconductor memory device according to example embodiments;

FIG. 12 is a perspective view for illustrating a semiconductor memory device according to example embodiments;

FIG. 13 is a cross-sectional view cut along lines D-D and E-E of FIG. 11;

FIG. 14 is a layout diagram for illustrating a semiconductor memory device according to example embodiments;

FIG. 15 is a perspective view for illustrating a semiconductor memory device according to example embodiments; and

FIG. 16 to FIG. 20 are diagrams of intermediate structures corresponding to intermediate steps of a semiconductor memory device manufacturing method according to example embodiments.

### DETAILED DESCRIPTIONS

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, the term “dummy” is used to refer to a component that has the same or similar structure and shape as other components but does not have a substantial function and exists only as a pattern in the device.

Like reference characters refer to like elements throughout.

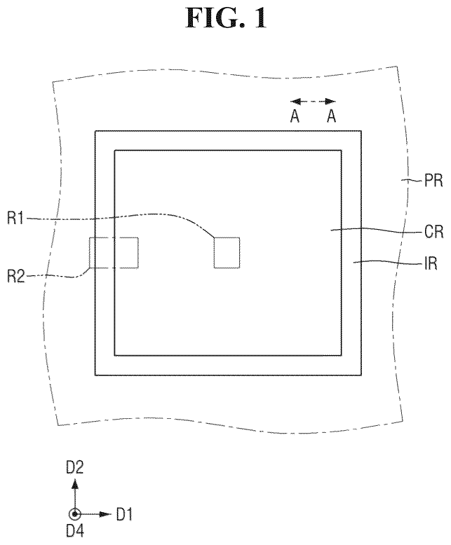

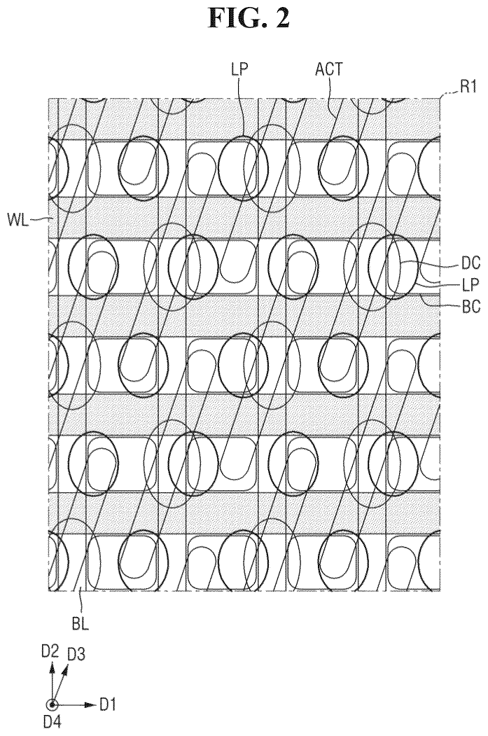

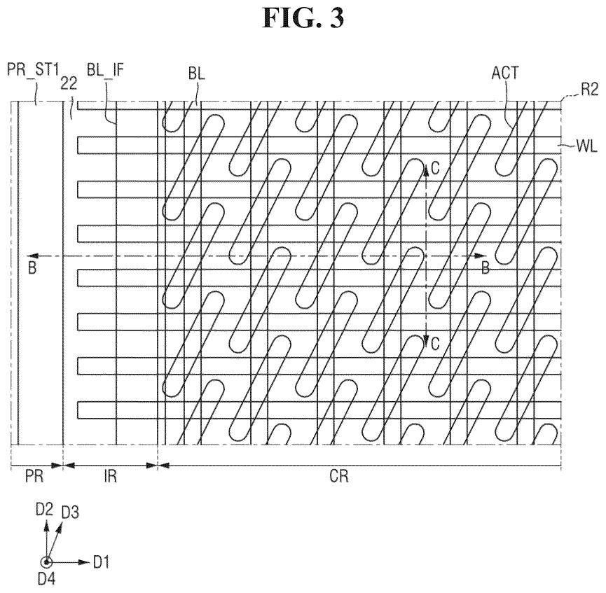

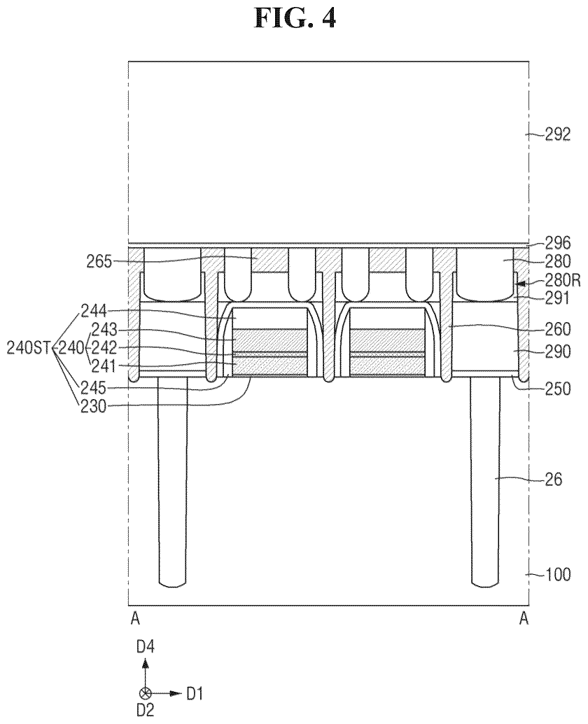

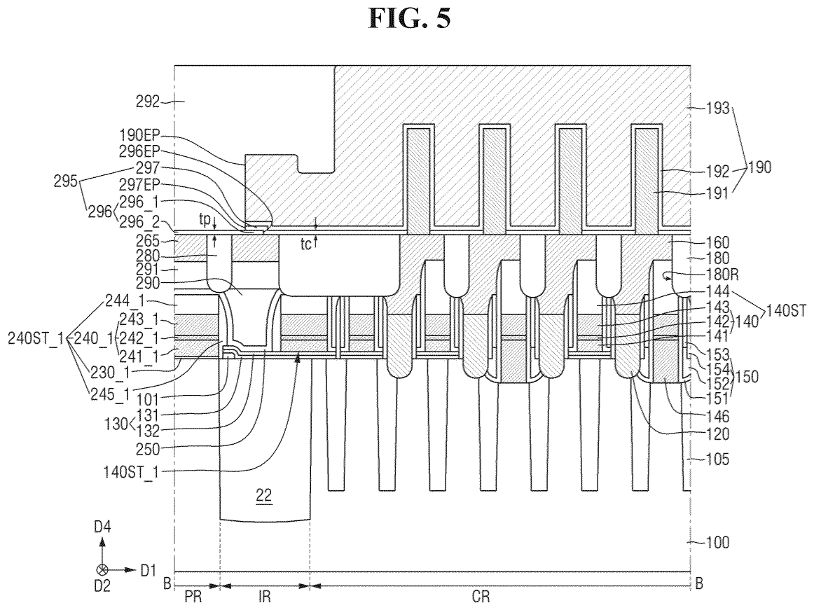

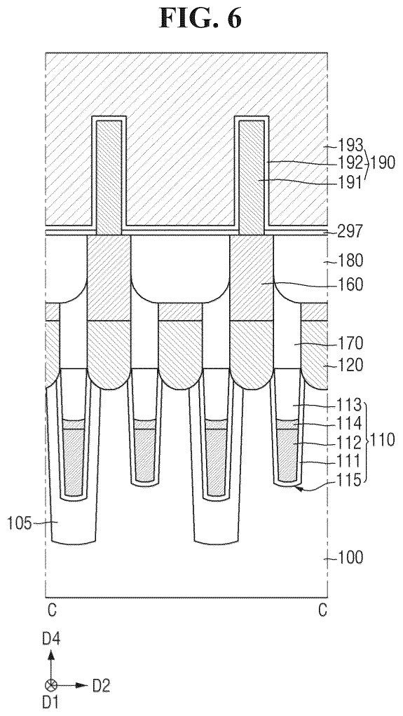

FIG. 1 is a schematic layout diagram of a semiconductor memory device according to example embodiments. FIG. 2 is a schematic layout of area R1 in FIG. 1. FIG. 3 is a schematic layout diagram of area R2 are in FIG. 1. FIG. 4 is an illustrative cross-sectional view taken along a line A-A in FIG. 1. FIG. 5 is a cross-sectional view cut along a line B-B in FIG. 3. FIG. 6 is a cross-sectional view cut along a line C-C in FIG. 3. For reference, FIG. 4 may be an illustrative cross-sectional view of a transistor formation area in a peripheral area.

Referring to FIG. 1 to FIG. 3, a semiconductor memory device according to some embodiments may include a cell area CR, an interface area IR, and a peripheral area PR.

The cell area CR may be a memory cell area of the semiconductor memory device. The cell area CR may include memory cells of a volatile memory device or memory cells of a non-volatile memory device. The peripheral area PR may include peripheral circuits necessary to operate the memory cells located in the cell area CR. For example, the cell area CR may be a memory cell area of DRAM (Dynamic Random Access Memory), while the peripheral area PR may be a core area or a peripheral circuit area of the DRAM.

The interface area IR may be disposed between the cell area CR and the peripheral area PR. The interface area IR may be formed along a perimeter of the cell area CR. The interface area IR may surround the cell area CR. The peripheral area PR may be defined as an area around the cell area CR. For example, the peripheral area PR may surround the interface area IR and the cell area CR.

The cell area CR may include a plurality of cell active areas ACT. The cell active area ACT may be defined by a cell element isolation film (e.g., cell element isolation film 105 in FIG. 5 and FIG. 6) formed in a substrate (e.g., substrate 100 in FIG. 4). As the design rule of the semiconductor memory device decreases, the cell active area ACT may have a bar shape extending in a diagonal line or an oblique line as shown in FIG. 2. For example, the cell active area ACT may extend lengthwise in a third direction D3.

Each of a plurality of gate electrodes may extend lengthwise in a first direction D1 and across the cell active area ACT. The plurality of gate electrodes may extend parallel to each other. Each of the plurality of gate electrodes may be embodied as, for example, each of a plurality of word-lines WL. The word-lines WL may extend parallel to each other. The word-lines WL may be spaced apart from each other by an equal spacing. A width of the word-line WL or a spacing between word-lines WL may be determined according to the design rule.

The two word-lines WLs adjacent to one another and extending lengthwise in the first direction D1 may allow each cell active area ACT to be divided into three portions. The cell active area ACT may include a storage connection area and a bit-line connection area. The bit-line connection area may be located at a middle portion of the cell active area ACT, while the storage connection area may be located at an end of the cell active area ACT.

A plurality of bit-lines BL extending lengthwise in a second direction D2 perpendicular to the extension direction of the word-line WL may be disposed on the word-lines WL. The plurality of bit-line BL may extend parallel to each other. The bit-lines BL may be arranged to be spaced apart from each other by the same (e.g., equal) spacing. A width of the bit-line BL or a spacing between bit-lines BLs may be determined according to the design rule.

A boundary bit-line BL_IF may extend lengthwise in a second direction D2 and in a parallel manner to the bit-line BL. At least a portion of the boundary bit-line BL_IF may be disposed so as to overlap the interface area IR in a fourth direction D4. For example, the boundary bit-line BL_IF may extend lengthwise in the second direction D2, while overlapping both the cell area CR and the interface area IR. Unlike what is illustrated, the semiconductor memory device according to some embodiments may not include the boundary bit-line BL_IF.

A boundary peripheral gate PR_ST1 may extend lengthwise in the second direction D2 and in a parallel manner to the boundary bit-line BL_IF. The boundary peripheral gate PR_ST1 may be disposed at a boundary between the interface area IR and the peripheral area PR. The boundary peripheral gate PR_ST1 may overlap the peripheral area PR. Unlike what is illustrated, in the semiconductor memory device according to some embodiments, the boundary peripheral gate PR_ST1 may extend lengthwise in the first direction D1. Furthermore, the semiconductor memory device according to some embodiments may not include the boundary peripheral gate PR_ST1.

A semiconductor memory device according to some implementations may include various contact arrangements formed on the cell active area ACT. The various contact arrangements may include, for example, a direct contact DC, a buried contact BC, and a landing pad LP, etc.

In this regard, the direct contact DC may refer to a contact that electrically connects the cell active area ACT to the bit-line BL. The buried contact BC may refer to a contact connecting the cell active area ACT to a lower electrode (e.g., first lower electrode 191 in FIG. 5 and FIG. 6) of a capacitor. In terms of an arrangement structure, a contact area between the buried contact BC and the cell active area ACT may be small. Accordingly, a conductive landing pad LP may be introduced to expand the contact area between the cell active area ACT and the buried contact BC, and to expand the contact area between the buried contact BC and the lower electrode (e.g., first lower electrode 191 in FIG. 5 and FIG. 6) of the capacitor.

The landing pad LP may be disposed between the cell active area ACT and the buried contact BC and may be disposed between the buried contact BC and the lower electrode (e.g., first lower electrode 191 in FIG. 5 and FIG. 6) of the capacitor. In the semiconductor memory device according to some implementations, the landing pad LP may be disposed between the buried contact BC and the lower electrode of the capacitor. Expanding the contact area via the introduction of the landing pad LP may allow a contact resistance between the cell active area ACT and the lower electrode of the capacitor to be reduced.

The direct contact DC may be connected to the bit-line connection area. The buried contact BC may be connected to the storage connection area. As the buried contact BC is disposed in each of both opposing ends of the cell active area ACT, the landing pad LP may be disposed adjacent to each of both opposing ends of the cell active area ACT and partially overlap with the buried contact BC. In other words, the buried contact BC may be formed to overlap the cell active area ACT and a cell element isolation film (e.g., cell element isolation film 105 in FIG. 5 and FIG. 6) between adjacent word-lines WL and between adjacent bit-lines BL.

The word-line WL may be formed as a structure buried in the substrate 100. The word-line WL may extend across the cell active area ACT between the direct contacts DC or between the buried contacts BC. As shown, two word-lines WL may extend through one cell active area ACT. As the cell active area ACT extends along the third direction D3, the extension direction of the word-line WL may have an angle smaller than 90 degrees with respective to the extension direction of the cell active area ACT.

The direct contacts DC and the buried contacts BC may be arranged in a symmetrical manner. Accordingly, the direct contacts DC and the buried contacts BC may be arranged in a straight line along the first direction D1 and the second direction D2. Unlike the direct contact DC and the buried contact BC, the landing pads LP may be arranged in a zigzag manner in the second direction D2 in which the bit-line BL extends. Further, the landing pads LP may overlap with the same portion of a side face of each bit-line BL in the first direction D1 in which the word-line WL extends. For example, each of landing pads LP in a first line may overlap the left side face of a corresponding bit-line BL, while each of the landing pads LP in a second line may overlap with a right side face of the corresponding bit-line BL.

Referring to FIG. 1 to FIG. 6, the semiconductor memory device according to some implementations may include the substrate 100, a plurality of cell gate structures 110, a plurality of bit-line structures 140ST, a plurality of storage pads 160, a capacitor structure 190, a peripheral gate structure 240ST, a peripheral wiring line 265, a peripheral etch stop film 296, and a cell etch stop film 297.

The substrate 100 may include the cell area CR, the interface area IR, and the peripheral area PR. The substrate 100 may be a silicon substrate or be made of an SOI (silicon-on-insulator). Alternatively, the substrate 100 may include silicon germanium, SGOI (silicon germanium on insulator), indium antimonide, lead tellurium compound, indium arsenic, indium phosphide, gallium arsenide or gallium antimonide. However, the present disclosure is not limited thereto.

The plurality of cell gate structures 110, the plurality of bit-line structures 140ST, the plurality of storage pads 160, and the capacitor structure 190 may be disposed in the cell area CR. The peripheral gate structure 240ST and the peripheral wiring line 265 may be disposed in the peripheral area PR.

The cell element isolation film 105 may be formed in the substrate 100 and in the cell area CR. The cell element isolation film 105 may have an STI (shallow trench isolation) structure with excellent element isolation ability. The cell element isolation film 105 may define the cell active areas ACT within the cell area CR. Each cell active area ACT defined by the cell element isolation film 105 may have an elongated island shape including a minor axis and a major axis as shown in FIG. 2. The cell active area ACT may have a diagonal extension shape to have an angle smaller than 90 degrees with respect to the extension direction of the word-line WL horizontally flush with the cell element isolation film 105. Further, the cell active area ACT may have a diagonal extension shape to have an angle smaller than 90 degrees with respect to an extension direction of the bit-line BL formed on the cell element isolation film 105.

In the substrate 100 and in the interface area IR, a cell area isolation film 22 with an STI structure may be formed. The cell area CR may be defined by the cell area isolation film 22.

Each of the cell element isolation film 105 and the cell area isolation film 22 may include, for example, at least one of a silicon oxide film, a silicon nitride film, and a silicon oxynitride film. However, the present disclosure is not limited thereto. In FIG. 5 and FIG. 6, each of the cell element isolation film 105 and the cell area isolation film 22 is shown to be formed as a single insulating film. However, this is only for convenience of illustration, and the present disclosure is not limited thereto. Depending on a width of each of the cell element isolation film 105 and the cell area isolation film 22, each of the cell element isolation film 105 and the cell area isolation film 22 may be formed as a single insulating film, or as a stack of a plurality of insulating films.

In FIG. 5, an upper surface of the cell element isolation film 105, an upper surface of the substrate 100, and an upper surface of the cell area isolation film 22 are shown to be horizontally flush with each other. For example, upper surfaces of the cell element isolation film 105, the substrate 100, and the cell area isolation film 22 may be coplanar with each other. However, this is only for convenience of illustration, and the present disclosure is not limited thereto. Hereinafter, the upper surface is defined based on a fourth direction D4. The fourth direction D4 is a vertical direction perpendicular to the upper surface of the substrate 100.

The cell gate structure 110 may be formed in the substrate 100 and the cell element isolation film 105. The cell gate structure 110 may be formed across the cell element isolation film 105 and the cell active area ACT defined by the cell element isolation film 105. The cell gate structure 110 may include a cell gate trench 115 formed in the substrate 100 and the cell element isolation film 105, a cell gate insulating film 111, a cell gate electrode 112, a cell gate capping pattern 113, and a cell gate capping conductive film 114. In this regard, the cell gate electrode 112 may act as the word-line WL. Unlike what is illustrated, in some embodiments, the cell gate structure 110 may not include the cell gate capping conductive film 114.

The cell gate insulating film 111 may extend along a side wall and a lower surface of the cell gate trench 115. The cell gate insulating film 111 may extend along a profile of at least a portion of the cell gate trench 115. The cell gate insulating film 111 may be formed of or include, for example, at least one of silicon oxide, silicon nitride, silicon oxynitride, or high dielectric constant materials having a higher dielectric constant than that of silicon oxide. The high dielectric constant material may be formed of or include, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be formed on the cell gate insulating film 111. The cell gate electrode 112 may contact the cell gate insulating film 111. The cell gate electrode 112 may fill a portion of the cell gate trench 115. The cell gate capping conductive film 114 may extend along an upper surface of the cell gate electrode 112. For example, the cell gate capping conductive film 114 may contact the upper surface of the cell gate electrode 112 and a side surface of the cell gate insulating film 111.

The cell gate electrode 112 may include at least one of metal, metal alloy, conductive metal carbonitride, conductive metal carbide, metal silicide, doped semiconductor material, conductive metal oxynitride, and conductive metal oxide. The cell gate electrode 112 may be formed of or include at least one of for example, TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni—Pt, Nb, NbN, NbC, Mo, MON, MoC, WC, Rh, Pd, Ir, Ag, Au, Zn, V, RuTiN, TiSi, TaSi, NiSi, CoSi, IrOx, RuOx, and combinations thereof. However, the present disclosure is not limited thereto. The cell gate capping conductive film 114 may be formed of or include, for example, polysilicon or polysilicon-germanium. However, the present disclosure is not limited thereto.

The cell gate capping pattern 113 may be disposed on the cell gate electrode 112 and the cell gate capping conductive film 114. The cell gate capping pattern 113 may contact an upper surface of the cell gate capping conductive film 114 and a side surface of the cell gate insulating film 111. The cell gate capping pattern 113 may fill a remaining portion of the cell gate trench 115 except for the cell gate insulating film 111, the cell gate electrode 112 and the cell gate capping conductive film 114. The cell gate insulating film 111 is shown to extend along a side wall of the cell gate capping pattern 113. However, the present disclosure is not limited thereto. The cell gate capping pattern 113 may be formed of or include, for example, at least one of silicon nitride SiN, silicon oxynitride SiON, silicon oxide SiO₂, silicon carbonitride SiCN, silicon oxycarbonitride SiOCN, and combinations thereof.

Although not shown, an impurity doped area may be formed on at least one side of the cell gate structure 110. The impurity doped area may act as a source/drain area of the transistor.

The bit-line structure 140ST may include a cell conductive line 140 and a cell line capping film 144. The cell conductive line 140 may be formed on the substrate 100 including the cell gate structure 110, and on the cell element isolation film 105 formed in the substrate 100. The cell conductive line 140 may intersect a cell element isolation film 105, and the cell active area ACT defined by the cell element isolation film 105. The cell conductive line 140 may be formed to intersect with the cell gate structure 110. In this regard, the cell conductive line 140 may act as the bit-line BL.

The cell conductive line 140 may be embodied as a multi-film. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the cell element isolation film 105. Although the cell conductive line 140 is shown to be composed of the three films, the present disclosure is not limited thereto.

Each of the first to third cell conductive films 141, 142, and 143 may include, for example, at least one of a semiconductor material doped with impurities, a conductive silicide compound, a conductive metal, nitride metal, and a metal alloy. For example, the first cell conductive film 141 may include a doped semiconductor material, the second cell conductive film 142 may include at least one of the conductive silicide compound and the conductive metal nitride, and the third cell conductive film 143 may include at least one of metal and metal alloy. However, the present disclosure is not limited thereto.

A bit-line contact 146 may be formed between the cell conductive line 140 and the substrate 100. That is, the cell conductive line 140 may be formed on the bit-line contact 146. For example, the bit-line contact 146 may be formed at a point where the cell conductive line 140 intersects a center portion of the cell active area ACT having an elongated island shape. The bit-line contact 146 may be formed between the bit-line connection area of the cell active area ACT and the cell conductive line 140.

The bit-line contact 146 may electrically connect the cell conductive line 140 and the substrate 100 to each other. In this regard, the bit-line contact 146 may act as the direct contact DC. The bit-line contact 146 may be formed of or include, for example, at least one of a semiconductor material doped with impurities, a conductive silicide compound, a conductive metal nitride, and a metal.

In FIG. 5, in an area in which the cell conductive line 140 overlaps an upper surface of the bit-line contact 146, the cell conductive line 140 may include the second cell conductive film 142 and the third cell conductive film 143. In an area in which the cell conductive line 140 does not overlap the upper surface of the bit-line contact 146, the cell conductive line 140 may include the first to third cell conductive films 141, 142, and 143.

In FIG. 5, it is shown that the bit-line contact 146 is not disposed between the cell conductive line 140 closest to the cell area isolation film 22 and the substrate 100. However, the present disclosure is not limited thereto. Alternatively, the bit-line contact 146 may be disposed between the cell conductive line 140 closest to the cell area isolation film 22 and the substrate 100.

The cell line capping film 144 may be disposed on the cell conductive line 140. The cell line capping film 144 may contact an upper surface of the cell conductive line 140. The cell line capping film 144 may extend in the second direction D2 and along the upper surface of the cell conductive line 140. In this regard, the cell line capping film 144 may be formed of or include, for example, at least one of silicon nitride, silicon oxynitride, silicon carbonitride, and silicon oxycarbonitride. In a semiconductor memory device according to some implementations, the cell line capping film 144 may include, for example, a silicon nitride film. The cell line capping film 144 is shown to be a single film. However, the present disclosure is not limited thereto. Unlike what is illustrated, in one example, the cell line capping film 144 may have a double layer structure. In another example, the cell line capping film 144 may have a triple layer structure. In still another example, the cell line capping film 144 may have a quadruple or greater layer structure.

A cell insulating film 130 may be formed on the substrate 100 and the cell element isolation film 105. More specifically, the cell insulating film 130 may be formed on the upper surface of the substrate 100 in an area in which the bit-line contact 146 and the storage contact 120 are not formed, and on the cell element isolation film 105 and the cell area isolation film 22. The cell insulating film 130 may contact upper surfaces of the substrate 100, the cell element isolation film 105, and the cell area isolation film 22. The cell insulating film 130 may be formed between the substrate 100 and the cell conductive line 140, and between the cell element isolation film 105 and the cell conductive line 140.

The cell insulating film 130 may be a single film. However, as illustrated, the cell insulating film 130 may be embodied as a multi-film including a first cell insulating film 131 and a second cell insulating film 132. For example, the first cell insulating film 131 may be formed of or include a silicon oxide film, while the second cell insulating film 132 may be formed of or include a silicon nitride film. In example embodiments, the first cell insulating film 131 may contact upper surfaces of the substrate 100, the cell element isolation film 105, and the cell area isolation film 22, and the second cell insulating film 132 may contact an upper surface of the first cell insulating film 131. However, the present disclosure is not limited thereto. Unlike what is illustrated, the cell insulating film 130 may be embodied as a triple film including a silicon oxide film, a silicon nitride film, and a silicon oxide film. However, the present disclosure is not limited thereto.

A cell buffer film 101 may be disposed between the cell insulating film 130 and the cell area isolation film 22. The cell buffer film 101 may contact an upper surface of the cell area isolation film 22, and the cell insulating film 130 may contact an upper surface of the cell buffer film 101. The cell buffer film 101 may be formed of or include, for example, a silicon oxide film. However, the present disclosure is not limited thereto.

A cell line spacer 150 may be disposed on a sidewall of each of the cell conductive line 140 and the cell line capping film 144. In an area in which the cell conductive line 140 overlaps the bit-line contact 146, the cell line spacer 150 may be formed on the substrate 100 and the cell element isolation film 105. The cell line spacer 150 may be disposed on sidewalls of the cell conductive line 140, the cell line capping film 144, and the bit-line contact 146. The cell line spacer 150 may contact sidewalls of the cell conductive line 140, the cell line capping film 144, and the bit-line contact 146.

However, in an area in which the cell conductive line 140 does not overlap the bit-line contact 146, the cell line spacer 150 may be disposed on the cell insulating film 130. The cell line spacer 150 may be disposed on the sidewalls of the cell conductive line 140 and the cell line capping film 144.

The cell line spacer 150 may be embodied as a single film. However, as shown, the cell line spacer 150 may have a multi-film structure including first to fourth cell line spacers 151, 152, 153, and 154. For example, each of the first to fourth cell line spacers 151, 152, 153, and 154 may include one of a silicon oxide film, a silicon nitride film, a silicon oxynitride film (SiON), a silicon oxycarbonitride film (SiOCN), air, or a combination thereof. However, the present disclosure is not limited thereto.

For example, the second cell line spacer 152 may not be disposed on the cell insulating film 130, but may be disposed on the sidewall of the bit-line contact 146. In FIG. 3 and FIG. 5, the bit-line structure 140ST may extend in an elongated manner in the second direction D2. The cell line spacer 150 may be disposed on a long side wall extending in the second direction D2 among side walls of the bit-line structure 140ST.

In FIG. 5, a dummy bit-line structure 140ST_1 may be disposed on the cell area isolation film 22. The dummy bit-line structure 140ST_1 may have the same structure as that of the bit-line structure 140ST. For example, the dummy bit-line structure 140ST_1 may include the cell conductive line 140 and the cell line capping film 144. In this regard, the cell conductive line 140 of the dummy bit-line structure 140ST_1 may be the boundary bit-line BL_IF.

A fence pattern 170 may be disposed on the substrate 100 and the cell element isolation film 105. The fence pattern 170 may be formed to overlap the cell gate structure 110 formed in the substrate 100 and the cell element isolation film 105 in the fourth direction D4. The fence pattern 170 may be disposed between the bit-line structures 140ST extending lengthwise in the second direction D2. The fence pattern 170 may include, for example, at least one of silicon oxide, silicon nitride, silicon oxynitride, and combinations thereof.

The storage contact 120 may be disposed between the cell conductive lines 140 adjacent to each other in the first direction D1. The storage contact 120 may be disposed between fence patterns 170 adjacent to each other in the second direction D2. The storage contact 120 may contact side surfaces of the fence patterns 170 and the cell lines spacers 150. The storage contact 120 may overlap a portion of the substrate 100 and a portion of the cell element isolation film 105 between adjacent cell conductive lines 140. The storage contact 120 may contact the substrate 100 and the cell element isolation film 105. The storage contact 120 may be connected to the storage connection area of the cell active area ACT. In this regard, the storage contact 120 may act as the buried contact BC.

The storage contact 120 may include, for example, at least one of a semiconductor material doped with impurities, a conductive silicide compound, a conductive metal nitride, and a metal.

The storage pad 160 may be formed on the storage contact 120. The storage pad 160 may contact an upper surface of the storage contact 120. The storage pad 160 may be electrically connected to the storage contact 120. The storage pad 160 may be connected to the storage connection area of the cell active area ACT. In this regard, the storage pad 160 may act as the landing pad LP.

The storage pad 160 may overlap with a portion of an upper surface of the bit-line structure 140ST. The storage pad 160 may include, for example, at least one of a semiconductor material doped with impurities, a conductive silicide compound, a conductive metal nitride, a conductive metal carbide, a metal, and a metal alloy.

The pad isolation insulating film 180 may be formed on the storage pad 160 and the bit-line structure 140ST. For example, the pad isolation insulating film 180 may be disposed on the cell line capping film 144. The pad isolation insulating film 180 may contact the storage pad 160 and the bit-line structure 140ST. For example, the pad isolation insulating film 180 may contact the cell line capping film 144. The pad isolation insulating film 180 may define the storage pad 160 as each of a plurality of isolated areas. The pad isolation insulating film 180 may not cover an upper surface of the storage pad 160. A pad isolation recess 180R may isolate adjacent storage pads 160 from each other. The pad isolation insulating film 180 may fill the pad isolation recess 180R. The pad isolation insulating film 180 may isolate the storage pads 160 from each other. For example, based on the upper surface of the substrate 100, a vertical level of an upper surface of the storage pad 160 may be equal to a vertical level of an upper surface of the pad isolation insulating film 180. For example, upper surfaces of the storage pad 160 and the pad isolation insulating film 180 may be coplanar.

The pad isolation insulating film 180 may include an insulating material and may electrically isolate adjacent ones of the plurality of storage pads 160 from each other. For example, the pad isolation insulating film 180 may be formed of or include at least one of a silicon oxide film, a silicon nitride film, a silicon oxynitride film, a silicon oxycarbonitride film, and a silicon carbonitride film.

A peripheral element isolation film 26 may be formed in the substrate 100 and in the peripheral area PR. The peripheral element isolation film 26 may define a peripheral active area in the peripheral area PR. An upper surface of the peripheral element isolation film 26 is shown as being coplanar with the upper surface of the substrate 100. However, the present disclosure is not limited thereto. The peripheral element isolation film 26 may include, but is not limited to, at least one of, for example, a silicon oxide film, a silicon nitride film, and a silicon oxynitride film.

The peripheral gate structure 240ST may be disposed on the substrate 100 and in the peripheral area PR. The peripheral gate structure 240ST may be disposed on the peripheral active area defined by the peripheral element isolation film 26.

The peripheral gate structure 240ST may include a peripheral gate insulating film 230, a peripheral gate conductive film 240, and a peripheral capping film 244 sequentially stacked on the substrate 100. For example, the peripheral capping film 244 may contact an upper surface of the peripheral gate conductive film 240, and the peripheral gate conductive film 240 may contact an upper surface of the peripheral gate insulating film 230. The peripheral gate structure 240ST may include a peripheral spacer 245 disposed on a sidewall of the peripheral gate conductive film 240 and a sidewall of the peripheral capping film 244.

The peripheral gate conductive film 240 may include first to third peripheral conductive films 241, 242, and 243 sequentially stacked on the peripheral gate insulating film 230. In one example, no additional conductive film may be disposed between the peripheral gate conductive film 240 and the peripheral gate insulating film 230. In another example, unlike what is illustrated, an additional conductive film, such as a work function conductive film, may be disposed between the peripheral gate conductive film 240 and the peripheral gate insulating film 230.

Although two peripheral gate structures 240ST are shown as being disposed between adjacent peripheral element isolation films 26, this is only for convenience of illustration, and the present disclosure is not limited thereto.

A block conductive structure 240ST_1 may be disposed between the cell area CR and the peripheral area PR. A portion of the block conductive structure 240ST_1 is shown as overlapping with the cell area isolation film 22. However, the present disclosure is not limited thereto. The block conductive structure 240ST_1 may be a conductive structure closest to the dummy bit-line structure 140ST_1 in the first direction D1.

The block conductive structure 240ST_1 may include a block gate insulating film 230_1, a block conductive line 240_1, and a block capping film 244_1 sequentially stacked on the substrate 100. The block conductive structure 240ST_1 may include a block spacer 245_1 disposed on a sidewall of the block conductive line 240_1 and a sidewall of the block capping film 244_1. In this regard, the block conductive line 240_1 may be a boundary peripheral gate PR_ST1.

The block conductive line 240_1 may include a first-first to a first-third block conductive films 241_1, 242_1, and 243_1 sequentially stacked on the block gate insulating film 230_1. A stacked film structure of the block conductive line 240_1 between the block gate insulating film 230_1 and the block capping film 244_1 may be the same as a stacked film structure of the peripheral gate conductive film 240.

The peripheral gate structure 240ST and the block conductive structure 240ST_1 may be positioned at the same level. In this regard, “A and B being positioned at the same level” may include A and B being formed in the same manufacturing process. Each of the peripheral gate conductive film 240 and the block conductive line 240_1 may have the same stacked structure as that of the cell conductive line 140.

The first peripheral conductive film 241 and the first-first block conductive film 241_1 may include the same material as that of the first cell conductive film 141. The second peripheral conductive film 242 and the first-second block conductive film 242_1 may include the same material as that of the second cell conductive film 142. The third peripheral conductive film 243 and the first-third block conductive film 243_1 may include the same material as that of the third cell conductive film 143.

The peripheral gate insulating film 230 and the block gate insulating film 230_1 may include the same material. The peripheral gate insulating film 230 and the block gate insulating film 230_1 may be formed of or include, for example, silicon oxide, silicon nitride, silicon oxynitride, or a high dielectric constant material having a higher dielectric constant than that of silicon oxide.

The peripheral spacer 245 and the block spacer 245_1 may include the same material. For example, the peripheral spacer 245 and the block spacer 245_1 may be formed of or include at least one of silicon nitride, silicon oxynitride, silicon oxide, silicon carbonitride, silicon oxycarbonitride, and combinations thereof. Although each of the peripheral spacer 245 and the block spacer 245_1 is shown as being embodied as a single film, this is only for convenience of illustration and the present disclosure is not limited thereto. In another example, each of the peripheral spacer 245 and the block spacer 245_1 may be embodied as a stack of multilayers.

The peripheral capping film 244 and the block capping film 244_1 may include the same material. For example, each of the peripheral capping film 244 and the block capping film 244_1 may include at least one of a silicon nitride film, silicon oxynitride, and silicon oxide.

A lower etch stop film 250 may be disposed on the substrate 100. The lower etch stop film 250 may contact upper surfaces of the substrate 100 and the peripheral element isolation film 26. The lower etch stop film 250 may be formed according to a profile of the peripheral gate structure 240ST and a profile of the block conductive structure 240ST_1. The lower etch stop film 250 may extend along a sidewall of the dummy bit-line structure 140ST_1. For example, the lower etch stop film 250 may include at least one of silicon nitride, silicon oxynitride, silicon carbonitride, and silicon oxycarbonitride.

A lower peripheral interlayer insulating film 290 may be disposed on the lower etch stop film 250. The lower peripheral interlayer insulating film 290 may contact an upper surface of the lower etch stop film 250. The lower peripheral interlayer insulating film 290 may be disposed around the peripheral gate structure 240ST. The lower peripheral interlayer insulating film 290 may be disposed on the cell area isolation film 22 and between the dummy bit-line structure 140ST_1 and the block conductive structure 240ST_1.

The lower peripheral interlayer insulating film 290 may include an oxide-based insulating material. An upper surface of the lower peripheral interlayer insulating film 290 may be coplanar with an upper surface of the lower etch stop film 250 extending along an upper surface of the peripheral gate structure 240ST.

An upper peripheral interlayer insulating film 291 is disposed on the peripheral gate structure 240ST and the lower peripheral interlayer insulating film 290. The upper peripheral interlayer insulating film 291 may cover the peripheral gate structure 240ST and the lower peripheral interlayer insulating film 290. For example, based on the upper surface of the substrate 100, a vertical level of the upper surface of the upper peripheral interlayer insulating film 291 may be the same as a vertical level of an upper surface of the cell line capping film 144.

The upper peripheral interlayer insulating film 291 includes a different material from that of the lower peripheral interlayer insulating film 290. The upper peripheral interlayer insulating film 291 may include, for example, a nitride-based insulating material. For example, the upper peripheral interlayer insulating film 291 may be formed of or include silicon nitride.

A peripheral contact plug 260 may be disposed on each of both opposing sides of the peripheral gate structure 240ST. The peripheral contact plug 260 may extend through the upper peripheral interlayer insulating film 291 and the lower peripheral interlayer insulating film 290 and then extend to the substrate 100 in the peripheral area PR. For example, the peripheral contact plug 260 may contact the upper peripheral interlayer insulating film 291, the lower peripheral interlayer insulating film 290, and the substrate 100. The peripheral contact plug 260 is connected to the substrate 100 in the peripheral area PR.

The peripheral wiring line 265 may be disposed on the peripheral gate structure 240ST. The peripheral wiring line 265 may be disposed on the upper peripheral interlayer insulating film 291 and the peripheral contact plug 260. The peripheral wiring line 265 may contact the upper peripheral interlayer insulating film 291 and the peripheral contact plug 260. The peripheral contact plug 260 is connected to the peripheral wiring line 265. The peripheral wiring lines 265 may be isolated from each other via a line isolation recess 280R. A width of the line isolation recess 280R may vary. A line isolation insulating film 280 may fill the line isolation recess 280R. The line isolation insulating film 280 may isolate the peripheral wiring lines 265 from each other. For example, the line isolation insulating film 280 may contact the peripheral wiring lines 265.

The peripheral contact plug 260 and the peripheral wiring line 265 may include the same material as that of the storage pad 160. The peripheral contact plug 260 and the peripheral wiring line 265 may be positioned at the same level as that of the storage pad 160. An upper surface of the peripheral wiring line 265 may be coplanar with the upper surface of the storage pad 160.

The peripheral etch stop film 296 is disposed in the peripheral area PR. The peripheral etch stop film 296 is disposed on the peripheral wiring line 265 and the line isolation insulating film 280. The peripheral etch stop film 296 may contact upper surfaces of the peripheral wiring line 265 and the line isolation insulating film 280. The peripheral etch stop film 296 is not disposed on the storage pad 160.

The cell etch stop film 297 is disposed in a cell area CR. The cell etch stop film 297 is disposed on the storage pad 160 and the pad isolation insulating film 180. The cell etch stop film 297 may contact upper surfaces of the storage pad 160 and the pad isolation insulating film 180. The cell etch stop film 297 is not disposed on the peripheral gate structure 240ST.

In some embodiments, a second thickness tc of the cell etch stop film 297 may be equal to a first thickness tp of the peripheral etch stop film 296. An upper surface of the cell etch stop film 297 on cell area CR may be coplanar with an upper surface of the peripheral etch stop film 296 in the peripheral area PR. As used herein, thickness refers to the thickness or height measured in a direction perpendicular to a top surface of the substrate 100 (e.g., a vertical direction or fourth direction D4).

In some embodiments, the second thickness tc of the cell etch stop film 297 may be different from the first thickness tp of the peripheral etch stop film 296. The upper surface of the cell etch stop film 297 on cell area CR may not be coplanar with the upper surface of the peripheral etch stop film 296 in the peripheral area PR.

The cell etch stop film 297 includes a different material from that of the peripheral etch stop film 296. For example, the cell etch stop film 297 may be formed of or include silicon boron nitride (SiBN), and the peripheral etch stop film 296 may include silicon carbonitride (SiCN).

In some embodiments, the peripheral etch stop film 296 does not extend into the cell area CR. The peripheral etch stop film 296 extends to a portion of the interface area IR. The cell etch stop film 297 does not extend to the peripheral area PR. The cell etch stop film 297 extends to the interface area IR. A side end 296EP of the peripheral etch stop film 296 and a side end 297EP of the cell etch stop film 297 are disposed in the interface area IR.

The side end 296EP of the peripheral etch stop film 296 and the side end 297EP of the cell etch stop film 297 are disposed on the cell area isolation film 22.

In some embodiments, the peripheral etch stop film 296 includes a first portion 296_1, which overlaps the cell etch stop film 297 in the fourth direction D4, and a second portion 296_2, which does not overlap the cell etch stop film 297 in the fourth direction D4. The first portion 296_1 of the peripheral etch stop film 296 is disposed in the interface area IR. In the interface area IR, a portion of the peripheral etch stop film 296, that is, the first portion 296_1 thereof overlaps with the cell etch stop film 297 in the fourth direction D4.

The side end 297EP of the cell etch stop film 297 is disposed on the upper surface of the peripheral etch stop film 296. The cell etch stop film 297 covers the side end 296EP of the peripheral etch stop film 296. The cell etch stop film 297 extends onto a portion of the upper surface of the peripheral etch stop film 296.

In other words, the etch stop film 295 including the peripheral etch stop film 296 and the cell etch stop film 297 is disposed in the cell area CR, the interface area IR, and the peripheral area PR. The maximum thickness tc+tp of a portion of the etch stop film 295 in the interface area IR is greater than each of a thickness tc of a portion of the etch stop film 295 in the cell area CR and a thickness tp of a portion of the etch stop film 295 in the peripheral area PR. The etch stop film 295 in the interface area IR includes a first portion with the first thickness tp, a second portion with the second thickness tc, and a third portion with a third thickness tc+tp. The first portion is adjacent to the peripheral area PR, the second portion is adjacent to the cell area CR, and the third portion is disposed between the first portion and the second portion. Each of the first portion and the second portion may have a single film structure, while the third portion may have a double film structure.

The capacitor structure 190 may be disposed on the storage pad 160. A portion of the capacitor structure 190 may be disposed on the cell etch stop film 297. A portion of the capacitor structure 190 may extend through the cell etch stop film 297 so as to be electrically connected to the storage pad 160. The capacitor structure 190 includes the first lower electrode 191, a first capacitor dielectric film 192, and a first upper electrode 193. For example, the first upper electrode 193 may have a plate shape.

The first lower electrode 191 may be disposed on the storage pad 160. For example, a lower surface of the first lower electrode 191 may contact an upper surface of the storage pad 160. The first lower electrode 191 is shown as having a pillar shape. However, the present disclosure is not limited thereto. In another example, the first lower electrode 191 may have a cylindrical shape. The first capacitor dielectric film 192 is formed on the first lower electrode 191. The first capacitor dielectric film 192 may be formed according to a profile of the first lower electrode 191. The first capacitor dielectric film 192 may contact upper and side surfaces of the first lower electrode 191 and an upper surface of cell etch stop film 297. The first upper electrode 193 is formed on the first capacitor dielectric film 192. The first upper electrode 193 may contact upper and side surfaces of the first capacitor dielectric film 192. The first upper electrode 193 may surround an outer wall of the first lower electrode 191. A shape of the edge portion of the first upper electrode 193 is not limited to what is shown.

The first capacitor dielectric film 192 overlaps with the first upper electrode 193 in the fourth direction D4. The first capacitor dielectric film 192 is not disposed in an area in which the first capacitor dielectric film 192 does not overlap with the first upper electrode 193 in the fourth direction D4.

The cell etch stop film 297 overlaps the capacitor structure 190 in the fourth direction D4. The cell etch stop film 297 is not disposed in an area in which the cell etch stop film 297 does not overlap the capacitor structure 190 in the fourth direction D4. A side end 190EP of the capacitor structure 190 is a side end of the first upper electrode 193 or a side end of the first capacitor dielectric film 192. The side end 190EP of the capacitor structure 190 may be aligned with the side end 297EP of the cell etch stop film 297 in a vertical direction D4.

The first portion 296_1 of the peripheral etch stop film 296 overlaps the capacitor structure 190 in the fourth direction D4. The second portion 296_2 of the peripheral etch stop film 296 does not overlap with the capacitor structure 190 in the fourth direction D4.

Each of the first lower electrode 191 and the first upper electrode 193 may be formed of or include a doped semiconductor material, a conductive metal nitride such as titanium nitride, tantalum nitride, niobium nitride or tungsten nitride, etc., a metal such as ruthenium, iridium, titanium or tantalum, etc., or a conductive metal oxide, such as iridium oxide or niobium oxide, etc. However, the present disclosure is not limited thereto. The first upper electrode 193 is shown as being embodied as a single film. However, the present disclosure is not limited thereto. The first upper electrode 193 may include a stack of a plurality of conductive films, wherein the conductive films may include different conductive materials.

The first capacitor dielectric film 192 may include, but is not limited to, one of, for example, silicon oxide, silicon nitride, silicon oxynitride, high dielectric constant material, and combinations thereof. In the semiconductor memory device according to some embodiments, the first capacitor dielectric film 192 may include a stacked film structure in which a zirconium oxide film, an aluminum oxide film, and a zirconium oxide film are sequentially stacked. In the semiconductor memory device according to some embodiments, the first capacitor dielectric film 192 may include a dielectric film including hafnium (Hf). In the semiconductor memory device according to some embodiments, the first capacitor dielectric film 192 may have a stacked structure of a ferroelectric material film and a paraelectric material film.

An interlayer insulating film 292 may be disposed on the peripheral etch stop film 296. The interlayer insulating film 292 covers the side end 190EP of the capacitor structure 190 and the side end 297EP of the cell etch stop film 297. The interlayer insulating film 292 may contact the side end 190EP of the capacitor structure 190 and the side end 297EP of the cell etch stop film 297. The interlayer insulating film 292 may be formed of or include, for example, an oxide-based insulating material. However, the present disclosure is not limited thereto.

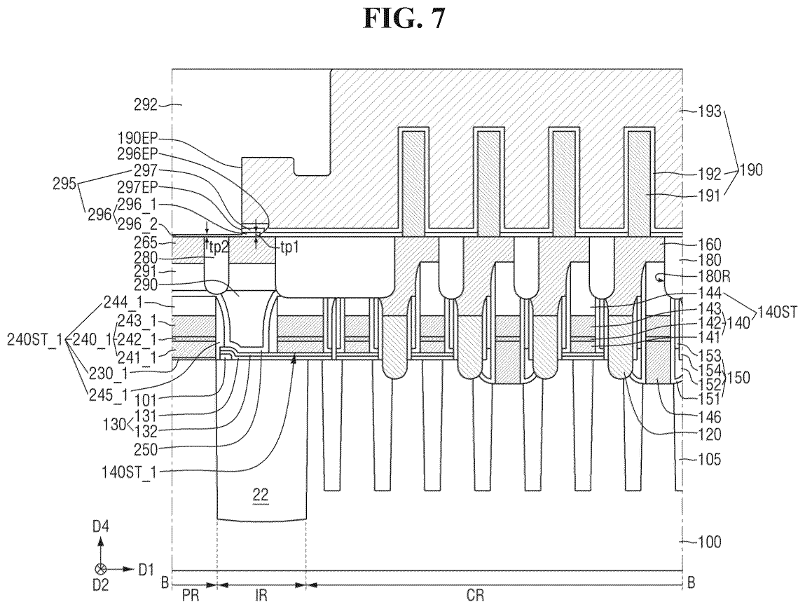

FIG. 7 to FIG. 10 are diagrams for illustrating a semiconductor memory device according to example embodiments. For convenience of description, following descriptions are mainly based on differences thereof from what have been described above with reference to FIG. 1 to FIG. 6. Duplicate descriptions will not be repeated.

Referring to FIG. 7, in the semiconductor memory device according to some embodiments, a thickness tp1 of the first portion 296_1 of the peripheral etch stop film 296 is greater than a thickness tp2 of the second portion 296_2 of the peripheral etch stop film 296.

For example, when etching the first upper electrode 193, the first capacitor dielectric film 192 and the cell etch stop film 297 may be etched together. At this time, a portion of the peripheral etch stop film 296 may be etched together therewith. Accordingly, the thickness tp1 of the first portion 296_1 of the peripheral etch stop film 296 that overlaps with the cell etch stop film 297 may be greater than the thickness tp2 of the second portion 296_2 of the peripheral etch stop film 296 that does not overlap the cell etch stop film 297.

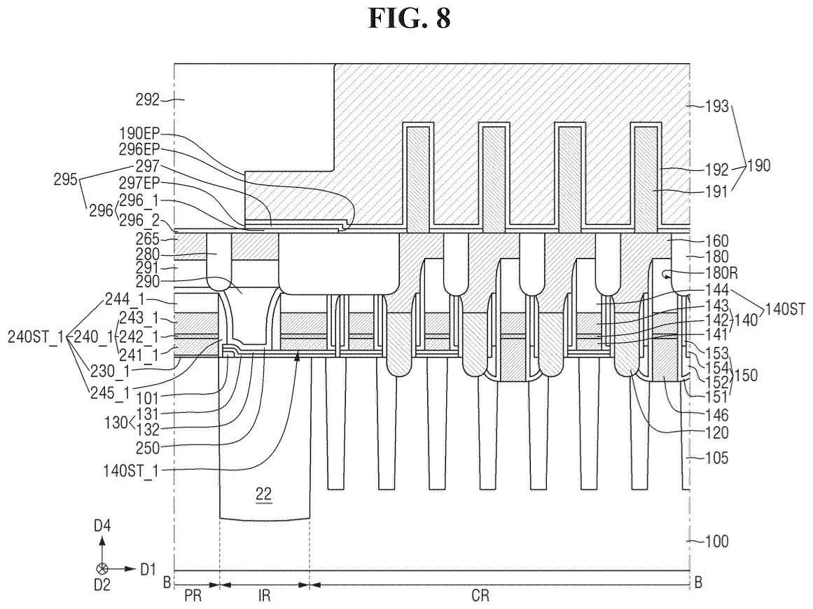

Referring to FIG. 8, in the semiconductor memory device according to some embodiments, the peripheral etch stop film 296 extends to the cell area CR. A portion of the peripheral etch stop film 296 is disposed in the cell area CR. The side end 296EP of the peripheral etch stop film 296 is disposed in the cell area CR. The first portion 296_1 of the peripheral etch stop film 296 is disposed in the interface area IR and the cell area CR.

The peripheral etch stop film 296 does not extend to the storage pad 160 closest to the cell area isolation film 22. The peripheral etch stop film 296 does not cover the upper surface of the storage pad 160 closest to the cell area isolation film 22.

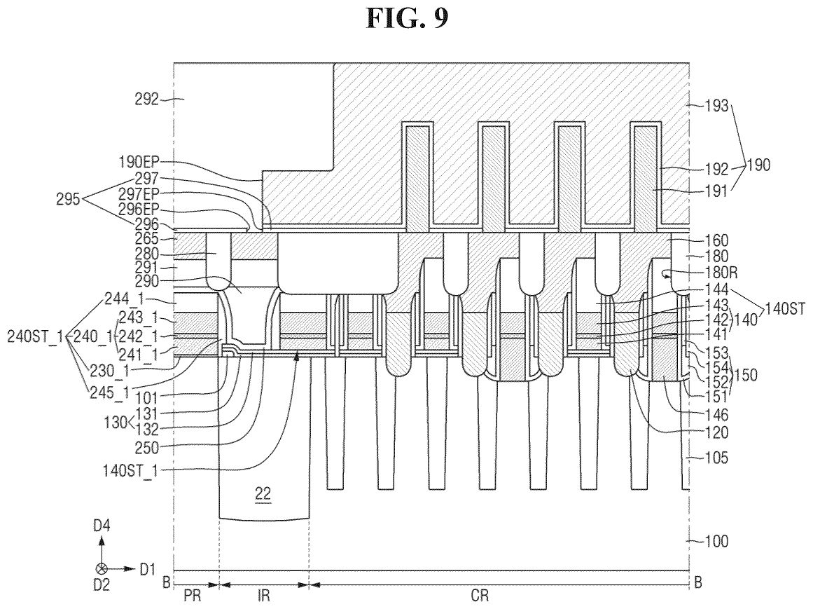

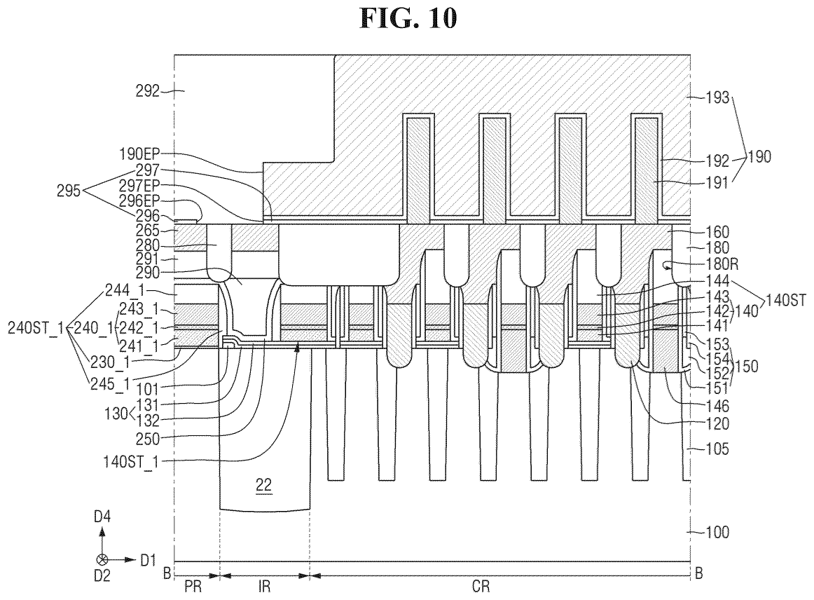

Referring to FIG. 9 and FIG. 10, in the semiconductor memory device according to some embodiments, the peripheral etch stop film 296 does not overlap the cell etch stop film 297 in the fourth direction D4. The side end 296EP of the peripheral etch stop film 296 is spaced apart from the side end 297EP of the cell etch stop film 297 in a horizontal direction parallel to the upper surface of substrate 100. The side end 296EP of the peripheral etch stop film 296 faces the side end 297EP of the cell etch stop film 297 in the horizontal direction (for example, the first direction D1) parallel to the upper surface of substrate 100.

The peripheral etch stop film 296 does not overlap with the capacitor structure 190 in the fourth direction D4.

Referring to FIG. 9, in the semiconductor memory device according to some embodiments, the side end 296EP of the peripheral etch stop film 296 is disposed in the interface area IR. The etch stop film 295 including the peripheral etch stop film 296 and the cell etch stop film 297 may not cover a portion of the peripheral wiring line 265 in the interface area IR so as to be exposed.

Referring to FIG. 10, in the semiconductor memory device according to some embodiments, the side end 296EP of the peripheral etch stop film 296 is disposed in the peripheral area PR. The side end 296EP of the peripheral etch stop film 296 may be disposed on a portion of the peripheral gate structure 240ST (that is, the block conductive structure 240ST_1) closest to the cell area isolation film 22. The etch stop film 295 including the peripheral etch stop film 296 and the cell etch stop film 297 may not cover a portion of the peripheral wiring line 265 in the interface area IR and a portion of the peripheral wiring line 265 in the peripheral area PR so as to be exposed.

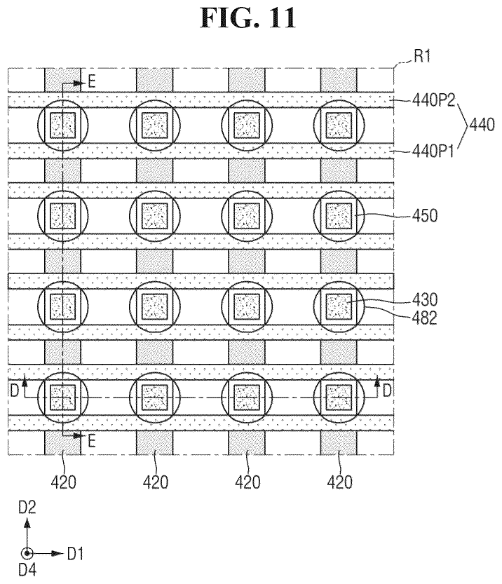

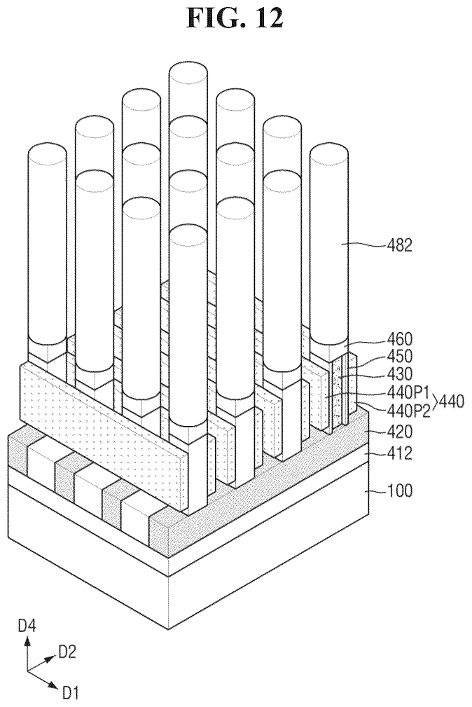

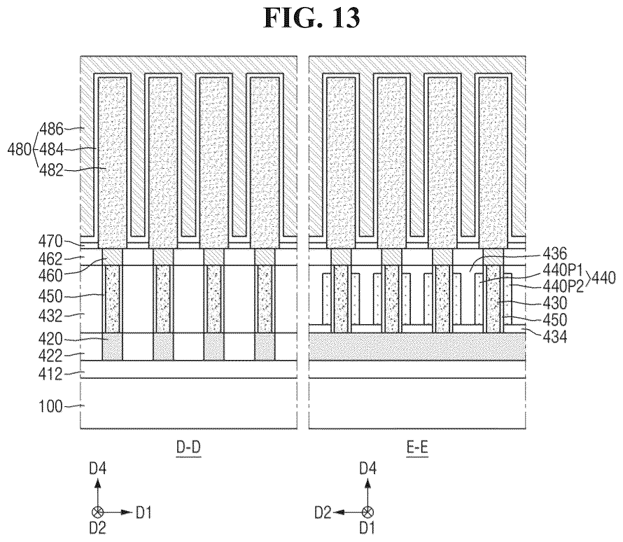

FIG. 11 is a layout diagram for illustrating a semiconductor memory device according to some embodiments. FIG. 12 is a perspective view for illustrating a semiconductor memory device according to some embodiments. FIG. 13 is a cross-sectional view cut along lines D-D and E-E of FIG. 11.

For reference, FIG. 11 may be an enlarged view of area R1 (the cell area CR) in FIG. 1. Furthermore, in the semiconductor memory device where FIG. 11 is applied to the cell area CR, a cross section (for example, a cross section taken along a line B-B in FIG. 3) of a boundary portion of the cell area is different from that in FIG. 5.

Referring to FIG. 11 to FIG. 13, a semiconductor memory device according to some embodiments may include the substrate 100, a plurality of first conductive lines 420, a channel layer 430, a gate electrode 440, a gate insulating film 450, and a capacitor 480. The semiconductor memory device according to some embodiments may be a memory device including a vertical channel transistor (VCT). The vertical channel transistor may refer to a structure in which a channel length of the channel layer 430 extends from the substrate 100 along a vertical direction (e.g., the fourth direction D4).

A lower insulating layer 412 may be disposed on the substrate 100. The plurality of first conductive lines 420 may be disposed on the lower insulating layer 412 and may be spaced apart from each other in the first direction D1 and extend lengthwise in the second direction D2. A plurality of first insulating patterns 422 may be disposed on the lower insulating layer 412 so as to fill a space between adjacent ones of the plurality of first conductive lines 420. The plurality of first insulating patterns 422 may extend lengthwise in the second direction D2. An upper surface of the plurality of first insulating patterns 422 may be position at the same vertical level as that of an upper surface of the plurality of first conductive lines 420. For example, upper surfaces of the plurality of first insulating patterns 422 and the plurality of first conductive lines 420 may be coplanar. Each of the plurality of first conductive lines 420 may function as a bit-line.

Each of the plurality of first conductive lines 420 may include at least one of a semiconductor material doped with impurities, a metal, a conductive metal nitride, a conductive metal silicide, a conductive metal oxide, or a combination thereof. For example, each of the plurality of first conductive lines 420 may include at least one of polysilicon doped with impurities, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof, but may not be limited thereto. Each of the plurality of first conductive lines 420 may include a single layer or multiple layers made of the aforementioned materials. In some embodiments, each of the plurality of first conductive lines 420 may be formed of or include graphene, carbon nanotube, or a combination thereof.

The channel layer 430 may have a matrix form in which channels are spaced apart from each other in each of the first direction D1 and the second direction D2 and are disposed on the plurality of first conductive lines 420, respectively. Each channel of the channel layer 430 may have a first width according to the first direction D1 and a first vertical dimension according to the fourth direction D4, wherein the first vertical dimension may be greater than the first width. In this regard, the fourth direction D4 may intersect the first direction D1 and the second direction D2, and may be, for example, a direction perpendicular to the upper surface of the substrate 100. For example, the first vertical dimension may be about 2 to 10 times of the first width. However, the disclosure is not limited thereto. A bottom portion of each channel of the channel layer 430 may function as a third source/drain area (not shown), while a top portion of each channel of the channel layer 430 may function as a fourth source/drain area (not shown). A portion of each channel of the channel layer 430 between the third and fourth source/drain areas may function as a channel area (not shown).

In some embodiments, the channel layer 430 may be formed of or include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multiple layers made of the oxide semiconductor. In some examples, the channel layer 430 may have a bandgap energy greater than that of silicon. For example, the channel layer 430 may have a bandgap energy of about 1.5 eV to about 5.6 eV. For example, the channel layer 430 may have optimal channel performance when the channel layer 430 has a bandgap energy of about 2.0 eV to 4.0 eV. For example, the channel layer 430 may be made of polycrystalline or amorphous, but may not be limited thereto. In some embodiments, the channel layer 430 may be formed of or include graphene, carbon nanotubes, or a combination thereof.

The gate electrode 440 may extend lengthwise in the first direction D1 and may be formed on both side walls of each channel of the channel layer 430. The gate electrode 440 may include a first sub-gate electrode 440P1 facing toward a first side wall of the channel layer 430, and a second sub-gate electrode 440P2 facing toward a second side wall opposite to the first side wall of the channel layer 430. As one channel of the channel layer 430 is disposed between the first sub-gate electrode 440P1 and the second sub-gate electrode 440P2, the semiconductor device may have a dual gate transistor structure. However, the technical spirit of the present disclosure is not limited thereto. The second sub-gate electrode 440P2 may be omitted and thus only the first sub-gate electrode 440P1 facing toward the first side wall of the channel layer 430 may be formed, so that a single gate transistor structure may be implemented. Description of a material of the gate electrode 440 may be the same as the description of the cell gate electrode 112.

The gate insulating film 450 surrounds a side wall of each channel of the channel layer 430 and may be interposed between each channel of the channel layer 430 and the gate electrode 440. The gate insulating film 450 may contact the side wall of the channel layer 430. For example, as shown, an entirety of a side wall of each channel of the channel layer 430 may be surrounded with the gate insulating film 450, and a portion of a side wall of the gate electrode 440 may contact the gate insulating film 450. In other embodiments, the gate insulating film 450 may extend in an extension direction of the gate electrode 440, that is, the first direction D1, and only two side walls facing toward the gate electrode 440 among all of side walls of each channel of the channel layer 430 may contact the gate insulating film 450. In some embodiments, the gate insulating film 450 may be embodied as a silicon oxide film, a silicon oxynitride film, a film made of a high dielectric constant material having a dielectric constant higher than that of the silicon oxide film, or a combination thereof.

A plurality of second insulating patterns 432 may extend lengthwise along the second direction D2 and may be disposed on the plurality of first insulating patterns 422, respectively. Each channel of the channel layer 430 may be disposed between adjacent two second insulating patterns 432 of the plurality of second insulating patterns 432. The plurality of second insulating patterns 432 may contact the channel layers 430. Further, a first buried layer 434 and a second buried layer 436 may be disposed between two adjacent second insulating patterns 432 and in a space between two adjacent channels of the channel layer 430. The first buried layer 434 may occupy a bottom portion of a space between two adjacent channels of the channel layer 430. The second buried layer 436 may be formed to fill a remainder of the space between the two adjacent channels of the channel layer 430 and may be disposed on the first buried layer 434. The first buried layer 434 may contact an upper surface of the plurality of first conductive lines 420, and the second buried layer 436 may contact an upper surface of the first buried layer 434. Each of the second buried layer 436 and the first buried layer 434 may contact at least a portion of the side surfaces of the gate insulating film 450. An upper surface of the second buried layer 436 may be coplanar with an upper surface of the channel layer 430, and the second buried layer 436 may cover an upper surface of the gate electrode 440. For example, the second buried layer 436 may contact the upper surface of the gate electrode 440. Alternatively, each of the plurality of second insulating pattern 432 and each of the plurality of first insulating patterns 422 may constitute a continuous material layer and thus may be monolithic. Alternatively, the second buried layer 436 and the first buried layer 434 may constitute a continuous material layer and thus may be monolithic.

Each capacitor contact 460 may be disposed on each channel of the channel layer 430. Each capacitor contact 460 may vertically overlap each channel of the channel layer 430. For example, each capacitor contact 460 may be disposed on and vertically overlap a corresponding one channel of the channel layer 430. In example embodiments, the capacitor contacts 460 may contact the channel layer 430. Thus, the capacitor contacts 460 may be arranged in a matrix form in which the capacitor contacts 460 are spaced apart from each other in each of the first direction D1 and the second direction D2. The capacitor contact 460 may be formed of or include at least one of polysilicon doped with impurities, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but may not be limited thereto. An upper insulating layer 462 may surround a side wall of each capacitor contact 460 and may be disposed on the plurality of second insulating patterns 432 and the second buried layer 436. For example, the upper insulating layer 462 may contact side walls of the capacitor contacts 460 and upper surfaces of the plurality of second insulating patterns 432.

A cell etch stop film 470 may be disposed on the upper insulating layer 462. The cell etch stop film 470 may contact an upper surface of the upper insulating layer 462. The capacitor 480 may be disposed on the cell etch stop film 470. The cell etch stop film 470 may correspond to the cell etch stop film 297 in FIG. 6.

The capacitor 480 may include a second lower electrode 482, a second capacitor dielectric film 484, and a second upper electrode 486. The second lower electrode 482 may extend through the cell etch stop film 470 so as to be electrically connected to an upper surface of the capacitor contact 460. For example, the second lower electrode 482 may contact the upper surface of the capacitor contact 460. The second lower electrode 482 may be formed as a pillar structure extending in the fourth direction D4. However, the present disclosure is not limited thereto. In some embodiments, the second lower electrode 482 may be positioned to vertically overlap the capacitor contact 460. The second lower electrodes 482 may be arranged in a matrix form in the first direction D1 and the second direction D2 and may be spaced apart from each other in the first direction D1 and the second direction D2. Alternatively, a landing pad (not shown) may be further disposed between the capacitor contact 460 and the second lower electrode 482, so that the second lower electrodes 482 may be arranged in a hexagonal shape.

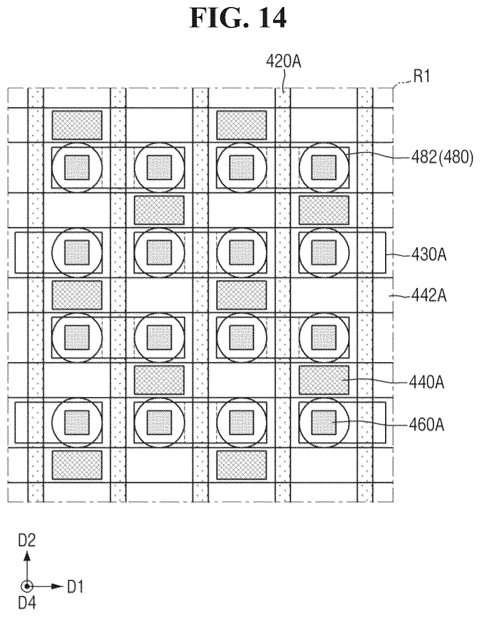

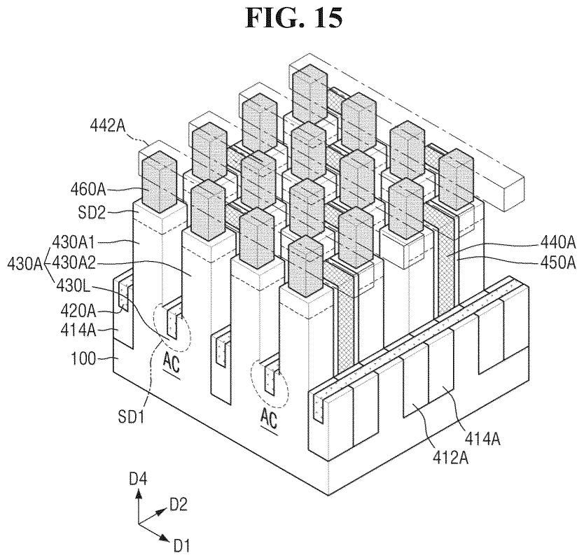

FIG. 14 is a layout diagram for illustrating a semiconductor memory device according to some example embodiments. FIG. 15 is a perspective view for illustrating a semiconductor memory device according to some example embodiments.

Referring to FIG. 14 and FIG. 15, the semiconductor memory device according to some embodiments may include the substrate 100, a plurality of first conductive lines 420A, channel structures 430A, contact gate electrodes 440A, a plurality of second conductive lines 442A, and the capacitors 480. The semiconductor memory device according to some embodiments may be a memory device including a vertical channel transistor (VCT).

A plurality of active areas AC may be defined in the substrate 100 by a first element isolation pattern 412A and a second element isolation pattern 414A. The channel structure 430A may be disposed in each of the active areas AC. The channel structure 430A may include a first active pillar 430A1 and a second active pillar 430A2 extending in a vertical direction, and a connector 430L connected to a bottom portion of the first active pillar 430A1 and a bottom portion of the second active pillar 430A2. A first source/drain area SD1 may be disposed in the connector 430L. A second source/drain area SD2 may be disposed in a top portion of each of the first and second active pillars 430A1 and 430A2. Each of the first active pillar 430A1 and the second active pillar 430A2 may constitute an independent unit memory cell.

The plurality of first conductive lines 420A may extend lengthwise in a direction intersecting the plurality of active areas AC. For example, the plurality of first conductive lines 420A may extend in the second direction D2. One of the plurality of first conductive lines 420A may be disposed on the connector 430L and between the first active pillar 430A1 and the second active pillar 430A2. One first conductive line 420A may be disposed on the first source/drain area SD1. Another first conductive line 420A adjacent to said one first conductive line 420A may be disposed between two channel structures 430A. One first conductive line 420A of the plurality of first conductive lines 420A may function as a common bit-line commonly included in two unit memory cells respectively corresponding to the first active pillar 430A1 and the second active pillar 430A2 respectively disposed on both sides of said one first conductive line 420A.

One contact gate electrode 440A may be disposed between two channel structures 430A adjacent to each other in the second direction D2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 respectively disposed on both side walls thereof. The gate insulating film 450A may be disposed between the contact gate electrode 440A and the first active pillar 430A1 and between the contact gate electrode 440A and the second active pillar 430A2. The plurality of second conductive lines 442A may extend lengthwise in the first direction D1. Each second conductive lines 442A may be disposed on an upper surface of each contact gate electrode 440A. Each of the plurality of second conductive lines 442A may function as a word-line of a semiconductor device.

A capacitor contact 460A may be disposed on the channel structure 430A. The capacitor contact 460A may be disposed on the second source/drain area SD2. The capacitor 480 may be disposed on the capacitor contact 460A.

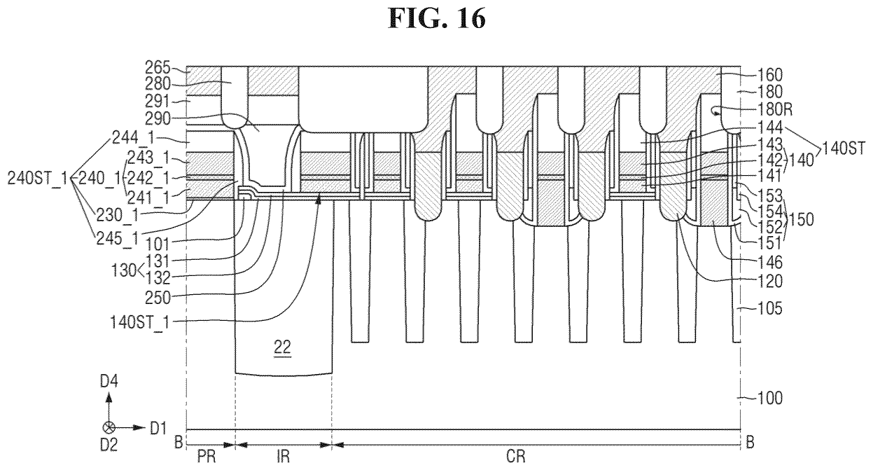

FIG. 16 to FIG. 20 are diagrams of intermediate structures corresponding to intermediate step of a method for manufacturing a semiconductor memory device according to some example embodiments. Descriptions about the manufacturing method duplicate with those set forth above using FIG. 1 to FIG. 10 are briefly set forth or omitted to avoid repetition.

Referring to FIG. 1 to FIG. 3 and FIG. 16, the substrate 100 including the cell area CR, the peripheral area PR, and the interface area IR is provided.

The cell gate structure 110 may be formed in the substrate 100 and in the cell area CR. The cell gate structure 110 may extend in an elongate manner in the first direction D1. The cell gate structure 110 may include the cell gate trench 115, the cell gate insulating film 111, the cell gate electrode 112, the cell gate capping pattern 113, and the cell gate capping conductive film 114.

Subsequently, the cell insulating film 130 may be formed on the substrate 100 and in the cell area CR. The cell insulating film 130 may not cover the peripheral area PR of the substrate 100 so as to be exposed.

Subsequently, the bit-line structure 140ST may be formed on the substrate 100 and in the cell area CR. The bit-line structure 140ST may include the cell conductive line 140 and the cell line capping film 144.

On the substrate 100 and in the peripheral area PR, the peripheral gate structure 240ST may be formed. The peripheral gate structure 240ST may include the peripheral gate insulating film 230, the peripheral gate conductive film 240, the peripheral capping film 244, and the peripheral spacer 245.

Subsequently, the storage pad 160 disposed on the side surface of the bit-line structure 140ST may be formed. The storage pads 160 may be isolated from each other via the pad isolation recess 180R. Furthermore, the peripheral contact plugs 260 respectively disposed on both opposing sides of the peripheral gate structure 240ST may be formed. The peripheral contact plug 260 and the peripheral wiring line 265 may be formed on the peripheral gate structure 240ST. The peripheral wiring lines 265 may be isolated from each other via the line isolation recess 280R.

For example, the storage pad 160, the peripheral contact plug 260, and the peripheral wiring line 265 may be formed simultaneously.

Subsequently, the pad isolation insulating film 180 filling the pad isolation recess 180R and the line isolation insulating film 280 filling the line isolation recess 280R may be formed. For example, the pad isolation insulating film 180 and the line isolation insulating film 280 may be formed simultaneously.

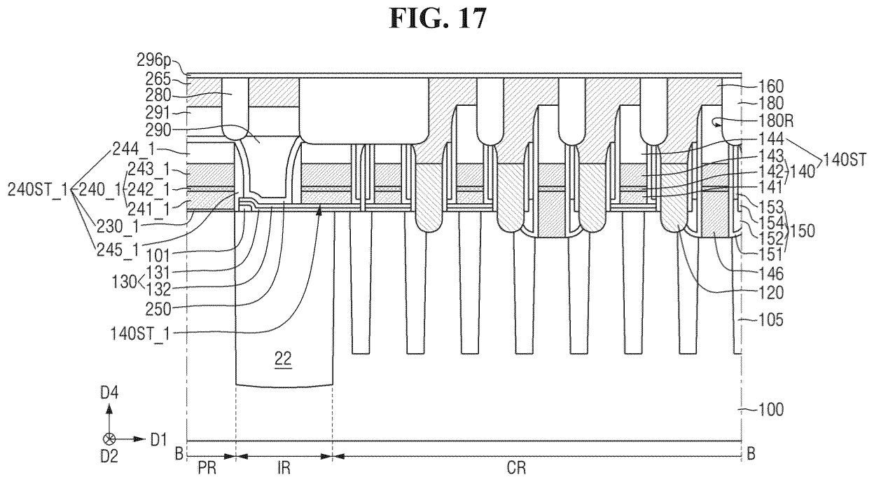

Referring to FIG. 17, a pre-peripheral etch stop film 296p may be formed on the storage pad 160, the pad isolation insulating film 180, the peripheral wiring line 265, and the line isolation insulating film 280. The pre-peripheral etch stop film 296p may cover the upper surface of the storage pad 160, the upper surface of the pad isolation insulating film 180, the upper surface of the peripheral wiring line 265, and the upper surface of the line isolation insulating film 280.

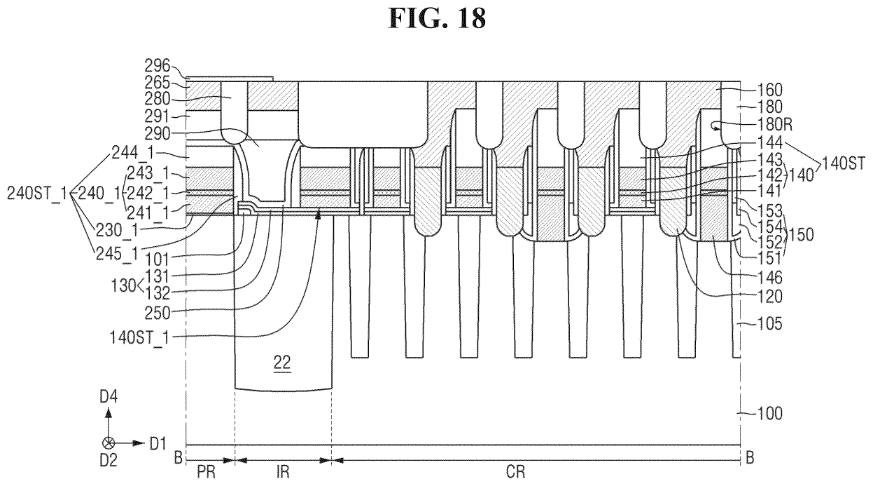

Referring to FIG. 18, a portion of the pre-peripheral etch stop film 296p disposed on the substrate 100 and in a portion of the interface area IR and the cell area CR may be removed. Accordingly, the peripheral etch stop film 296 having the side end 296EP disposed on the substrate 100 and in the interface area IR may be formed.

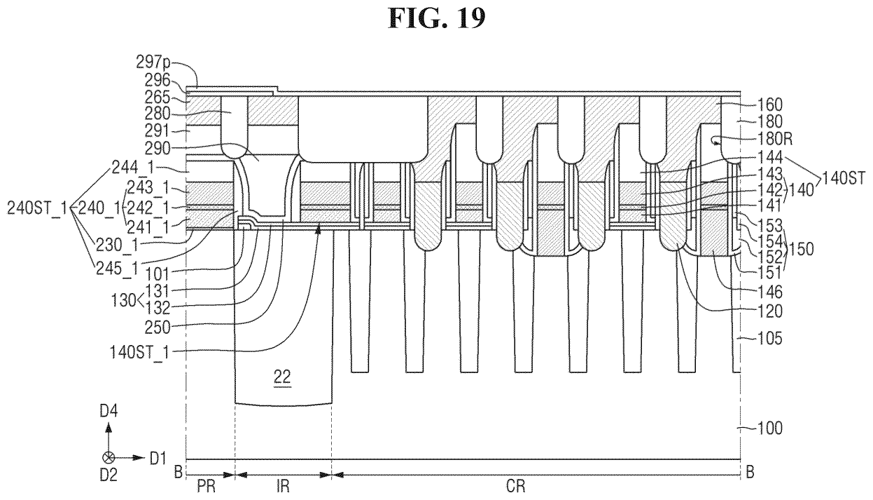

Referring to FIG. 19, a pre-cell etch stop film 297p may be formed on the peripheral etch stop film 296 so as to cover the peripheral area PR, the interface area IR, and the cell area CR. The pre-cell etch stop film 297p may cover the upper surface of the peripheral etch stop film 296, the side end 296EP of the peripheral etch stop film 296, and the upper surface of the peripheral wiring line 265, the upper surface of the pad isolation insulating film 180, and the upper surface of the storage pad 160 not covered with the peripheral etch stop film 296 so as to be exposed.

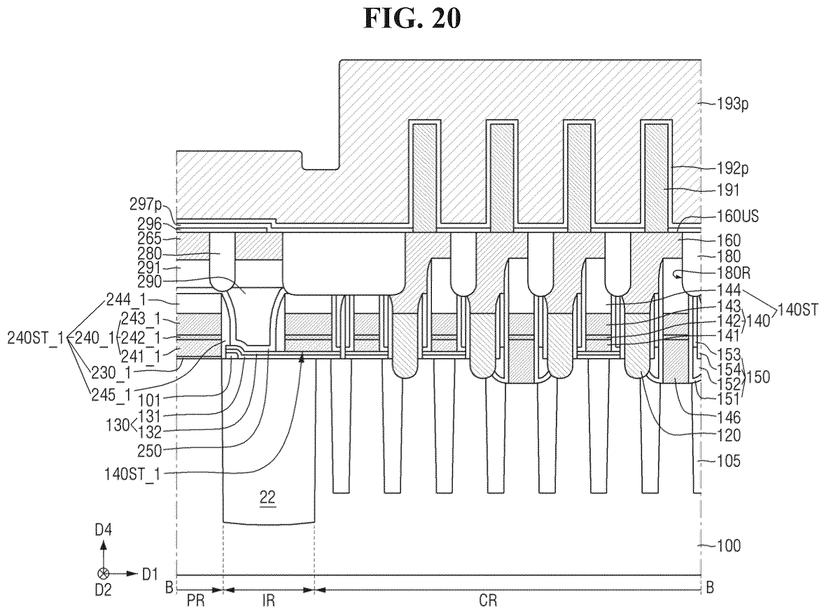

Referring to FIG. 20, the first lower electrode 191 extending through the pre-cell etch stop film 297p may be formed. The first lower electrode 191 is connected to the storage pad 160. When forming the first lower electrode 191, the peripheral area PR and the interface area IR may be protected with the etch stop film because a portion (a combination of the peripheral etch stop film 296 and the pre-cell etch stop film 297p) of the etch stop film disposed in the peripheral area PR and the interface area IR is thicker than a portion of the etch stop film in the cell area CR. Furthermore, the pre-cell etch stop film 297p includes silicon boron nitride (SiBN). Thus, a larger area of the upper surface of the storage pad 160 may not be covered with the pre-cell etch stop film 297p so as to be exposed. Therefore, while the peripheral area PR and the interface area IR are protected, the first lower electrode 191 may be formed so as to be in contact with the storage pad 160 by a set contact area size.

Subsequently, a pre-capacitor dielectric film 192p is formed on the first lower electrode 191. The pre-capacitor dielectric film 192p may be formed along the profile of the first lower electrode 191. The pre-capacitor dielectric film 192p may be formed on the pre-cell etch stop film 297p. The pre-capacitor dielectric film 192p may cover the cell area CR, the peripheral area PR, and the interface area IR.

Subsequently, a pre-upper electrode 193p is formed on the pre-capacitor dielectric film 192p. The pre-upper electrode 193p may cover the cell area CR, the peripheral area PR, and the interface area IR.

Next, referring to FIG. 5, the first upper electrode 193 may be formed by patterning the pre-upper electrode 193p. At this time, the pre-capacitor dielectric film 192p and the pre-cell etch stop film 297p may be patterned together therewith. Accordingly, the first capacitor dielectric film 192 and the cell etch stop film 297 may be formed.

In a semiconductor memory device according to some embodiments, the cell etch stop film 297 and the peripheral etch stop film 296 including the different materials are formed on the substrate 100 and in the cell area CR and the peripheral area PR, respectively. In other words, the cell etch stop film 297 in the cell area CR and the peripheral etch stop film 296 in the peripheral area PR are separated from each other. Thus, the material and the thickness of each of the cell etch stop film 297 and the peripheral etch stop film 296 in each of the cell area CR and the peripheral area PR may be freely adjusted depending on needs. Accordingly, the semiconductor memory device with improved reliability may be formed.

Furthermore, in the semiconductor memory device according to some embodiments, the peripheral etch stop film 296 including silicon carbonitride (SiCN) with a relatively low dielectric constant is disposed on the substrate 100 and in the peripheral area PR. Thus, the elements of the peripheral area PR and the capacitor structure 190 are electrically insulated from each other, such that the characteristics of the elements of the peripheral area PR may be improved.

Although embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, embodiments disclosed in the present disclosure are not intended to limit the technical idea of the present disclosure, but to describe the present disclosure. Indeed, the scope of the technical idea of the present disclosure is not limited by the disclosed embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. A semiconductor memory device comprising:
a substrate including a cell area and a peripheral area;
a peripheral gate structure on the substrate in the peripheral area;
a peripheral wiring line on the peripheral gate structure and connected to the substrate;
a peripheral etch stop film on the peripheral wiring line;
an element isolation film defining an active area in the cell area in the substrate;
a storage pad connected to the active area defined in the cell area;
a cell etch stop film on the storage pad; and
a capacitor structure extending through the cell etch stop film to contact the storage pad,
wherein the peripheral etch stop film and the cell etch stop film include materials different from each other.

2. The semiconductor memory device of claim 1,
wherein the peripheral etch stop film includes silicon carbonitride (SiCN), and
wherein the cell etch stop film includes silicon boron nitride (SiBN).

3. The semiconductor memory device of claim 1,
wherein the cell etch stop film is present in an area in which the cell etch stop film overlaps the capacitor structure in a vertical direction, which is perpendicular to an upper surface of the substrate, and
wherein the cell etch stop film is absent in an area in which the cell etch stop film does not overlap the capacitor structure in the vertical direction.

4. The semiconductor memory device of claim 1, wherein a first thickness of the peripheral etch stop film is equal to a second thickness of the cell etch stop film.

5. The semiconductor memory device of claim 1, wherein a first thickness of the peripheral etch stop film is different from a second thickness of the cell etch stop film.

6. The semiconductor memory device of claim 5, wherein the first thickness of the peripheral etch stop film is smaller than the second thickness of the cell etch stop film.

7. The semiconductor memory device of claim 1, wherein the cell etch stop film and the peripheral etch stop film do not overlap each other in each of the cell area and the peripheral area in a vertical direction, which is perpendicular to an upper surface of the substrate.

8. A semiconductor memory device comprising:
a substrate including a cell area, a peripheral area, and an interface area between the cell area and the peripheral area;
a peripheral gate structure on the substrate and in the peripheral area;
a peripheral wiring line on the peripheral gate structure;
an element isolation film defining an active area in the cell area in the substrate;
a storage pad on the active area defined in the cell area;
a peripheral etch stop film that is on the peripheral wiring line and is not on the storage pad;
a cell etch stop film that is on the storage pad and is not on the peripheral gate structure; and
a capacitor structure extending through the cell etch stop film to contact the storage pad.

9. The semiconductor memory device of claim 8, wherein a side end of the cell etch stop film and a side end of the peripheral etch stop film are disposed on the substrate and in the interface area.

10. The semiconductor memory device of claim 9, wherein the peripheral etch stop film includes:
a first portion that does not overlap the cell etch stop film in a vertical direction, which is perpendicular to an upper surface of the substrate; and
a second portion overlapping the cell etch stop film in the vertical direction.

11. The semiconductor memory device of claim 10, wherein the side end of the cell etch stop film is disposed on the peripheral etch stop film.

12. The semiconductor memory device of claim 10, wherein a thickness of the first portion is smaller than a thickness of the second portion.

13. The semiconductor memory device of claim 9, wherein the side end of the peripheral etch stop film is spaced apart from the side end of the cell etch stop film in a direction parallel to an upper surface of the substrate.

14. The semiconductor memory device of claim 8,
wherein a side end of the cell etch stop film is disposed on the substrate and in the interface area, and
wherein a side end of the peripheral etch stop film is disposed on the substrate and in the peripheral area.

15. The semiconductor memory device of claim 8,
wherein a side end of the cell etch stop film is disposed on the substrate and in the interface area, and
wherein a side end of the peripheral etch stop film is disposed on the substrate and in the cell area.

16. The semiconductor memory device of claim 15, wherein the side end of the cell etch stop film is disposed on the peripheral etch stop film.

17. The semiconductor memory device of claim 8, wherein the cell etch stop film and the peripheral etch stop film include materials different from each other.

18. A semiconductor memory device comprising:
a substrate including a cell area, a peripheral area, and an interface area between the cell area and the peripheral area;
a cell area isolation film defining the cell area in the substrate and in the interface area;
a bit-line structure on the substrate and in the cell area, wherein the bit-line structure includes a cell conductive line and a cell line capping film on the cell conductive line;
a cell gate electrode in the substrate and in the cell area and intersecting the cell conductive line;
an element isolation film defining an active area in the substrate and in the cell area;
a storage pad on a side surface of the bit-line structure and connected to the active area;
a cell etch stop film on the storage pad;
a capacitor structure including:
a lower electrode extending through the cell etch stop film to contact the storage pad;
a capacitor dielectric film on the lower electrode; and
an upper electrode on the capacitor dielectric film;
a peripheral gate structure on the substrate and in the peripheral area;
a peripheral wiring line on the peripheral gate structure and connected to the substrate; and
a peripheral etch stop film on the peripheral wiring line,
wherein a side end of the cell etch stop film is disposed on the cell area isolation film in the interface area.

19. The semiconductor memory device of claim 18,
wherein the cell etch stop film is present in an area in which the cell etch stop film overlaps the capacitor structure in a vertical direction, which is perpendicular to an upper surface of the substrate, and
wherein the cell etch stop film is absent in an area in which the cell etch stop film does not overlap the capacitor structure in the vertical direction.

20. The semiconductor memory device of claim 18, wherein a side end of the peripheral etch stop film is disposed on the substrate and in the interface area.
